(19) United States
(12) Patent Application Publication
(10) Pub. No.: US 2020/0235254 A1
(43) Pub. Date: Jul. 23, 2020

(54) LUMINESCENT SOLAR CONCENTRATOR USING A METAL-FREE EMITTER

(71) Applicants: INSTITUT NATIONAL DE LA RECHERCHE SCIENTIFIQUE, Quebec (CA); UNIVERSITY OF ELECTRONIC SCIENCE AND TECHNOLOGY OF CHINA, Chengdu (CN)

(72) Inventors: Yufeng ZHOU, Longueuil (CA); Daniele BENETTI, Montreal (CA); Xin TONG, Longueuil (CA); Lei JIN, Longueuil (CA); Zhiming M. WANG, Chengdu (CN); Dongling MA, Pointe-Claire (CA); Haiguang ZHAO, Montreal (CA); Federico ROSEI, Montreal (CA)

(73) Assignees: INSTITUT NATIONAL DE LA RECHERCHE SCIENTIFIQUE, Quebec, QC (CA); UNIVERSITY OF ELECTRONIC SCIENCE AND TECHNOLOGY OF CHINA, Chengdu (CN)

(21) Appl. No.: 16/486,109

(22) PCT Filed: Feb. 16, 2018
(86) PCT No.: PCT/CA2018/050176

§ 371 Date: Aug. 14, 2019

Related U.S. Application Data
(60) Provisional application No. 62/460,356, filed on Feb. 17, 2017.

(51) Int. Cl. H01L 31/055; C09K 11/65; C09K 11/02; C08L 29/04; C08L 33/10; C08L 39/06

(52) U.S. Cl. CPC H01L 31/055; C09K 11/65; C09K 11/025; B82Y 20/00; C08L 33/10; C08L 39/06; C08L 29/04

(57) ABSTRACT

A luminescent solar concentrator (LSC) comprising a metal-free emitter. The emitter may for example be carbon-based. In particular, the emitter may comprise colloidal carbon quantum dots, also called C-dots or C-QDs or C-dots. In embodiments of the invention, the surface of the C-dots is modified.

### CROSS REFERENCE TO RELATED APPLICATIONS

This application claims the benefit of U.S. provisional patent application Ser. No. 62/460,356, filed on Feb. 17, 2017. The content of the U.S. provisional patent application is incorporated herein in its entirety by reference.

### FIELD OF THE INVENTION

The present invention relates generally to luminescent solar concentrators (LSCs). More specifically, the invention relates to an LSC that uses an emitter that is metal-free, for example carbon-based. In embodiments of the invention, the emitter comprises colloidal carbon quantum dots, also called C-dots or C-QDs (herein C-dots). In other embodiments, the surface of the C-dots is modified.

### BACKGROUND OF THE INVENTION

Generating power directly from solar radiation represents a promising opportunity towards addressing the increasing demand for clean energy, also reducing environmental impact caused by excessive carbon emissions [1-5]. Every hour, radiation impinging from the sun would be sufficient to power the whole planet for one year [6]. During the past decades, single-crystal silicon has dominated the photovoltaic (PV) market, with a typical power conversion efficiency (PCE) in the range of 20-40% and good stability, exhibiting only a about 20% decrease in PCE after 20 years of exposure to sunlight. Despite their relatively high PCE and good stability, the price of PV modules is still not considered high [7].

Luminescent solar concentrators (LSCs) constitute an effective technology to reduce the cost of PV energy by decreasing the active area of traditional solar cells used for generating the same amount of power [8-12]. In addition, there is an increased interest in developing solar energy systems for building-integrated PV applications and LSCs with fine control of the colour and degree of transparency, which may prove to be an effective solution for purposes such as facades and rooftops [13].

An LSC typically consists of a plastic optical waveguide doped with highly emissive fluorophores. Following absorption of sunlight, the fluorophores re-emit photons at a lower energy by down-shifting (or higher energy by up-conversion) and these photons are guided towards the PV devices positioned at their edges by total internal reflection [14-16]. Ideally, suitable emitters for high efficiency LSCs should have near-unity photoluminescence quantum yield (PLQY), wide absorption spectrum with significant overlap with the solar spectrum, small overlap between absorption and PL spectra and good chemical- and photo-stability.

Besides conventional organic dyes and polymers, colloidal semiconducting nanocrystals, also called quantum dots (QDs), have recently been widely used as emitters in LSCs [17-23]. In general, QDs exhibit widely tunable absorption/emission spectra, thereby leading to a significant overlap with the distribution of solar radiation. In addition, they possess efficient photoluminescence (PL) properties, a large Stokes-shift (defined as the difference in wavelength between the positions of the band maxima of absorption and emission spectra) and improved photo-stability compared to dyes/polymers [17-24]. In particular, the large Stokes-shift is important for the realization of large-area LSCs with suppressed reabsorption losses as, in most of QDs, the PLQY is less than 100%.

The main challenges that have so far hampered the technological development of LSCs are the following: 1) commonly used inorganic QDs contain toxic elements, e.g. Cd, Pb. Even if CuInSe(S) and silicon QDs are less toxic, the synthesis procedure involves the use of toxic organic solvents [18,25,26]; 2) doped QDs or type-II QDs exhibit reduced reabsorption energy loss which is favorable for large-area LSCs. However, the PLQY of these QDs is typically not high (<20%) and they present a low photo-stability; 3) colloidal inorganic QDs are sensitive to oxygen/moisture/light exposure during synthesis, purification, and post-use.

Recent work has demonstrated that silicon QDs are promising emitters for high optical efficiency LSCs, as they have almost no energy loss because of zero reabsorption. This is due to the indirect band-gap of silicon QDs [25]. These LSCs exhibit an external optical efficiency of 2.85% (defined as the ratio between output power of LSCs collected from edges and solar input power through top surface). On the other hand, the synthetic procedure for silicon QDs is still challenging, as it requires the use of argon, helium and hydrogen under high pressure (1.4 torr), expensive facilities and extended (12 hours) post-treatment under ultraviolet (UV) light to improve stability [25]. This challenge may be addressed by using carbon QDs (also named carbon dots or C-dots).

C-dots represent an emerging class of non-toxic semiconducting nanomaterials [27-32]. C-dots are composed of non-toxic elements (C, N and O) and can be synthesized in large quantities via a solvothermal approach using abundant, low-cost precursors [33-37]. C-dots also exhibit a relatively high PLQY with tunable absorption up to the near infrared range [38]. For example, Kwon et al. synthesized colloidal C-dots with PLQY as high as 60% using a soft-template approach [39]. Compared to organic dyes/polymers and inorganic QDs such as Si, PbS/CdS and CdSe/CdS, C-dots exhibit good air-stability, which allows for the possibility to store them in ambient conditions. In addition, non-radiative emission can be inhibited by surface passivation and functionalization of C-dots, resulting in a large separation between the emission and absorption spectra. This, in turn could reduce the energy loss caused by reabsorption in large-area LSCs [40-42]. Fabrication of LSCs based on C-dots with small lateral area (4 cm²) is known in the art [43].

There is still a need for improved LSCs. In particular, there is a need for LSCs using emitters that are efficient, environmentally friendly and cost-effective.

### SUMMARY OF THE INVENTION

The inventors have designed and fabricated a new and improved LSC. The LSC according to the invention uses an emitter that is metal-free; in particular, the emitter comprises carbon material. In embodiments of the invention, the emitter comprises colloidal carbon quantum dots (C-dots). In other embodiments, the surface of the C-dots is modified. In yet other embodiments, the surface-modified C-dots and mixed with a polymer and/or monomers material.

The invention thus provides the following according to aspects thereof:
(1) A luminescent solar concentrator (LSC) comprising a metal-free emitter.
(2) A luminescent solar concentrator (LSC) comprising a carbon-based emitter.
(3) A luminescent solar concentrator (LSC) having an emitter that comprises carbon material.
(4) A luminescent solar concentrator (LSC) having an emitter that comprises colloidal carbon quantum dots (C-dots).
(5) A luminescent solar concentrator (LSC) having an emitter that comprises surface-modified colloidal carbon quantum dots (C-dots).
(6) A luminescent solar concentrator (LSC), which is metal-free.
(7) A luminescent solar concentrator (LSC) comprising carbon material and a polymer material.
(8) A luminescent solar concentrator (LSC) comprising colloidal carbon quantum dots (C-dots).
(9) A luminescent solar concentrator (LSC) comprising colloidal carbon quantum dots (C-dots) and a polymer material.
(10) A luminescent solar concentrator (LSC) comprising surface-modified colloidal carbon quantum dots (C-dots).
(11) A luminescent solar concentrator (LSC) comprising surface-modified colloidal carbon quantum dots (C-dots) and a polymer material.
(12) A luminescent solar concentrator (LSC) comprising a substrate having a surface coated with a material comprising carbon and a polymer.
(13) A luminescent solar concentrator (LSC) comprising a substrate having a surface coated with a material comprising colloidal carbon quantum dots (C-dots) and a polymer.
(14) A luminescent solar concentrator (LSC) comprising a substrate having a surface coated with a material comprising surface-modified colloidal carbon quantum dots (C-dots) and a polymer.
(15) A matrix for use in the manufacture of a luminescent solar concentrator (LSC), the matrix comprising a carbon material and a polymer material.
(16) A matrix for use in the manufacture of a luminescent solar concentrator (LSC), the matrix comprising colloidal carbon quantum dots (C-dots) and a polymer material.
(17) A matrix for use in the manufacture of a luminescent solar concentrator (LSC), the matrix comprising surface-modified colloidal carbon quantum dots (C-dots) and a polymer material.
(18) A substrate for use in the manufacture of a luminescent solar concentrator (LSC), the substrate being coated with a mixture comprising a carbon material and a polymer material.
(19) A substrate for use in the manufacture of a luminescent solar concentrator (LSC), the substrate being coated with a mixture comprising colloidal carbon quantum dots (C-dots) and a polymer material.
(20) A substrate for use in the manufacture of a luminescent solar concentrator (LSC), the substrate being coated with a mixture comprising surface-modified colloidal carbon quantum dots (C-dots) and a polymer material.
(21) A composition for use in the manufacture of a luminescent solar concentrator (LSC), the composition comprising a carbon material and a polymer material and/or a monomers material and/or a pre-polymer material and/or a precursor polymer material.
(22) A composition for use in the manufacture of a luminescent solar concentrator (LSC), the composition comprising colloidal carbon quantum dots (C-dots) and a polymer material and/or a monomers material and/or a pre-polymer material and/or a precursor polymer material.
(23) A composition for use in the manufacture of a luminescent solar concentrator (LSC), the composition comprising surface-modified colloidal carbon quantum dots (C-dots) and a polymer material and/or a monomers material and/or a pre-polymer material and/or a precursor polymer material.
(24) A method of manufacturing a luminescent solar concentrator (LSC), comprising: preparing a carbon material; providing a polymer material; mixing the carbon material and the polymer material to obtain the LSC.
(25) A method of manufacturing a luminescent solar concentrator (LSC), comprising: preparing colloidal carbon quantum dots (C-dots); providing a polymer material; mixing the C-dots and the polymer material to obtain the LSC.
(26) A method of manufacturing a luminescent solar concentrator (LSC), comprising: preparing colloidal carbon quantum dots (C-dots); providing a polymer material; mixing the surface-modified C-dots and the polymer material to obtain the LSC.
(27) A method of manufacturing a luminescent solar concentrator (LSC), comprising: preparing a carbon material; providing monomers material; mixing the carbon material and the monomers material; and conducting polymerization using an initiator to obtain the LSC.
(28) A method of manufacturing a luminescent solar concentrator (LSC), comprising: preparing colloidal carbon quantum dots (C-dots); providing monomers material; mixing the C-dots and the monomers material; and conducting polymerization using an initiator to obtain the LSC.
(29) A method of manufacturing a luminescent solar concentrator (LSC), comprising: preparing surface-modified colloidal carbon quantum dots (C-dots); providing monomers material; mixing the surface modified C-dots and the monomers material; and conducting polymerization using an initiator to obtain the LSC.
(30) A method of manufacturing a luminescent solar concentrator (LSC), comprising: preparing a carbon material; providing a substrate and a polymer material; mixing the carbon material, the polymer material and the solvent; and forming a layer of the mixture on a surface of the substrate.
(31) A method of manufacturing a luminescent solar concentrator (LSC), comprising: preparing colloidal carbon quantum dots (C-dots); providing a substrate and a polymer material; mixing the C-dots, the polymer material and the solvent; and forming a layer of the mixture on a surface of the substrate.
(32) A method of manufacturing a luminescent solar concentrator (LSC), comprising: preparing surface-modified colloidal carbon quantum dots (C-dots); providing a substrate and a polymer material; mixing the surface modified C-dots, the polymer material and the solvent; and forming a layer of the mixture on a surface of the substrate.
(33) A method of manufacturing a luminescent solar concentrator (LSC), comprising: preparing a carbon material; providing a polymer material; mixing the carbon material, the polymer material and the solvent; providing a mold constituted by first and second substrates separated by a spacer; and injecting the mixture into the mold.
(34) A method of manufacturing a luminescent solar concentrator (LSC), comprising: preparing colloidal carbon quantum dots (C-dots); providing a polymer material; mixing the C-dots, the polymer material and the solvent; providing a mold constituted by first and second substrates separated by a spacer; and injecting the mixture into the mold.
(35) A method of manufacturing a luminescent solar concentrator (LSC), comprising: preparing surface-modified colloidal carbon quantum dots (C-dots); providing and a polymer material; mixing the surface modified C-dots, the polymer material and the solvent; providing a mold constituted by first and second substrates separated by a spacer; and injecting the mixture into the mold.
(36) A method for preparing a matrix for use in the manufacture of a luminescent solar concentrator (LSC), the method comprising: preparing a carbon material; providing a polymer material; and mixing the carbon material and the polymer material to obtain the matrix.
(37) A method for preparing a matrix for use in the manufacture of a luminescent solar concentrator (LSC), the method comprising: preparing colloidal carbon quantum dots (C-dots); providing a polymer material; and mixing the C-dots and the polymer material to obtain the matrix.
(38) A method for preparing a matrix for use in the manufacture of a luminescent solar concentrator (LSC), the method comprising: preparing surface-modified colloidal carbon quantum dots (C-dots); providing a polymer material; and mixing the surface-modified C-dots and the polymer material to obtain the matrix.
(39) A method for preparing a matrix for use in the manufacture of a luminescent solar concentrator (LSC), the method comprising: preparing a carbon material; providing monomers material; mixing the carbon material and the monomers material; and conducting polymerization using an initiator to obtain the matrix.
(40) A method for preparing a matrix for use in the manufacture of a luminescent solar concentrator (LSC), the method comprising: preparing colloidal carbon quantum dots (C-dots); providing monomers material; mixing the C-dots and the monomers material; and conducting polymerization using an initiator to obtain the matrix.
(41) A method for preparing a matrix for use in the manufacture of a luminescent solar concentrator (LSC), the method comprising: preparing surface-modified colloidal carbon quantum dots (C-dots); providing monomers material; mixing the surface modified C-dots and the monomers material; and conducting polymerization using an initiator to obtain the matrix.
(42) A device for converting sunlight into electricity, comprising a luminescent solar concentrator (LSC) as defined in any one of (1)-(14) above and one or more photovoltaic cells provided at edges of the LSC.
(43) A device for converting sunlight into electricity, comprising at least one matrix as defined in any one of (15)-(17) above and one or more photovoltaic cells provided at edges of the matrix.
(44) A device for converting sunlight into electricity, comprising at least one substrate as defined in any one of (18)-(20) above and one or more photovoltaic cells provided at edges of the substrate.
(45) A method of manufacturing a device for converting sunlight into electricity, comprising using a composition as defined in any one of (21)-(23) above.
(46) A luminescent solar concentrator or matrix or substrate or composition or method or device according to any one of (1)-(45) above, wherein the surface-modified colloidal carbon quantum dots are modified with a base which is organic or inorganic; preferably, the base is an amine, NaOH or KOH.
(47) A luminescent solar concentrator or matrix or substrate or composition or method or device according to any one of (1)-(45) above, wherein the surface-modified colloidal carbon quantum dots are modified with an amine; preferably the amine is a long carbon-chain amine; more preferably an amine having a carbon chain of more than about 6 carbons.
(48) A luminescent solar concentrator or matrix or substrate or composition or method or device according to any one of (1)-(45) above, wherein the surface-modified colloidal carbon quantum dots are modified with oleyamine.
(49) A luminescent solar concentrator or matrix or substrate or composition or method or device according to any one of (1)-(48) above, having an input area (or surface sheet oriented toward the energy source) in a range between at least about 25 to about 2500 cm².
(50) A luminescent solar concentrator or matrix or substrate or composition or method or device according to any one of (1)-(49) above, having a thickness between about 20 μm to 2 mm; preferably between about 20 μm to about 150 μm; preferably between about 50 μm to 100 μm; preferably between about 1.5 mm to about 2.5 mm; preferably around 2 mm.
(51) A luminescent solar concentrator or matrix or substrate or composition or method or device according to any one of (1)-(50) above, wherein the polymer material comprises poly(lauryl methacrylate) (PLMA), polyvinylpyrrolidone (PVP), poly(vinyl alcohol), polyethylene glycols with average mol. wt. 1,000-1,000,000, or a combination thereof.
(52) A luminescent solar concentrator or matrix or substrate or composition or method or device according to any one of (1)-(51) above, wherein the monomers material comprises an alkyl acrylate, preferably an alkyl acrylate having about 4-12 carbon atoms in the alkyl group or an alkyl acrylate having an average of about 4-12 carbon atoms in its alkyl groups (CH₂═C(CH₃)COOCH₂(CH₂)ₙCH₃ wherein n=4-12, CH₂═C(H)COOCH₂(CH₂)ₙCH₃ wherein n=4-12) or an alkyl methacrylate such as ethylene glycol dimethacrylate (EGDM) or lauryl methacrylate; or a combination thereof.
(53) A luminescent solar concentrator or matrix or substrate or composition or method or device according to any one of (1)-(52) above, wherein the matrix is poly(lauryl methacrylate) (PLMA) polymer matrix.
(54) A luminescent solar concentrator or matrix or substrate or composition or method or device according to any one of (1)-(53) above, wherein the C-dots are embedded in poly(lauryl methacrylate) (PLMA) polymer matrix.
(55) A luminescent solar concentrator or matrix or substrate or composition or method or device according to any one of (1)-(52) above, wherein the C-dots are mixed with polyvinylpyrrolidone (PVP).
(56) A composition according to any one of (21)-(23) above, further comprising a solvent, and a concentration of the C-dots in the mixture is between about 5-100 mg/mL or is about 15 mg/mL.
(57) A method according to any one of (30)-(32) above, wherein the layer is formed on the surface of the substrate by spray deposition, spin coating or a combination thereof; preferably the substrate is a glass substrate.
(58) A method according to any one of (33)-(35) above, wherein the substrate is flexible or rigid and/or wherein the spacer is made of a flexible material, preferably the spacer is a flexible silicon rubber; preferably a thickness of the spacer is between about 1.5 mm to about 2.5 mm, preferably about 2 mm.

Other objects, advantages and features of the present invention will become more apparent upon reading of the following non-restrictive description of specific embodiments thereof, given by way of example only with reference to the accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In the appended drawings:

FIG. 1: Characterization of C-dots. (a,b) TEM and HRTEM images of the freshly synthesized C-dots (a) and the OLA-modified C-dots (b). The inset of (a) is a HRTEM image of C-dots. (c) Schematic illustration of surface modification of C-dots before and after phase transfer. (d) Absorption and PL spectra of C-dots under different surface treatments (excitation wavelength at 440 nm) with same concentration in different solvents. (e) PL decay curves collected at emission peak of 540 nm for C-dots under different surface treatments (excitation wavelength at 440 nm).

FIG. 2: Optical properties of the OLA-modified C-dot based LSCs. (a) Schematic demonstration of C-dot based LSCs integrated with PV device. (b) PL decay curves collected at emission peak of 540 nm for the OLA-modified C-dots in hexane and polymer matrix (excitation wavelength at 440 nm). (c) Absorption and PL spectra measured at different optical paths for the OLA-modified C-dot based LSCs. (d,e) PL peak position (d) and PL full width at half maximum (FWHM) ratio (e) of the OLA-modified C-dot based LSCs as a function of optical path.

FIG. 3: Performance of the OLA-modified C-dot based LSCs. (a,b) Photographs of colorless large-area OLA-modified C-dot based LSCs with dimension of 0.2×10×10 cm³ under ambient (a) and one sun illumination (b). (c,d) External optical efficiency (c) and internal quantum efficiency (d) of LSCs with different concentration of the OLA-modified C-dots. (e,f) PL spectra of C-dots based LSC (e) and PL intensity of different types of QDs based LSCs (f) upon UV exposure (1.3 W/cm²) for several hours.

FIG. 4: Analytical model of the performance of OLA-modified C-dot based LSC with 0.5 C₀. (a) Overlap between absorption and emission of the C-dots at different concentrations. (b) External optical efficiency of 0.5 C₀ C-dot based LSC with the PLQY varied from 0.25 to 1. The square points are the experimental data obtained with the electro-optical method of comparing the J_{sc}. (c) External optical efficiency of 0.5 C₀ C-dot based LSC with PLQY=1 when varied the quality factor from 0.4 (the value measured) up to 100 (d) Internal quantum efficiency of 0.5 C₀ LSCs with different PLQY. The dotted lines are calculated for C-dots with PLQY=0.5 and Q_{F}=50 (red dotted line), PLQY=0.75 and Q_{F}=10 (green dashed line). The square points are the experimental data obtained with the method of comparing the different I_{sc}.

FIG. 5: PL spectra of (a) the freshly prepared C-dots in methanol and (b) the OLA-modified C-dots in hexane at different excitation wavelengths. (c,d) Photographs of the C-dots in methanol and in hexane under room light (c) and UV light (d).

FIG. 6: PL spectra of the C-dots under different conditions. Excitation wavelength is 440 nm.

FIG. 7: (a) Absorption spectra of OLA-modified C-dots in methanol solution with different concentrations (C₀, 0.5 C₀ and 0.25 C₀). Inset is the Beer's law relationship between absorbance at 564 nm and concentration of C-dots. The concentration is defined as C₀=2.8 mg/L when A=0.12 @ 564 nm. (b) Absorption coefficient spectrum of OLA-modified C-dots in methanol solution. The C-dots show a similar absorption coefficient to that of inorganic QD [46].

FIG. 8: Integrated PL area of the OLA-modified C-dot based LSCs as a function of optical path. The PL spectra are taken from FIG. 2c.

FIG. 9: (a) Schemes of tandem thin-film LSCs based on UV C-dots (top) and visible C-dots(bottom). (b) The absorption and emission spectra of UV C-dots (#1, top) and visible NaOH treated C-dots (#2, bottom) based thin-film LSCs and absorption spectrum of PVP on a glass substrate.

FIG. 10: (a,b) Photographs of thin-film LSCs based on C-dots #1 (a) and C-dots #2 (b) under ambient light. (c-f) Photographs of tandem thin-film LSCs based C-dots LSCs under UV illumination (c) and one sun AM 1.5G illumination (f), and thin film LSCs based on C-dots #1 (d) and C-dots #2 (e) under one sun AM 1.5G illumination. The dimensional size of LSCs is 10×10 cm².

FIG. 11: PL decay curves collected at 540 nm wavelength of the OLA-modified C-dot based LSCs (G=10) without or with UV exposure (1.3 W/cm²) for 4 hours.

FIG. 12: Stability of the QD-polymer composites. PL spectra of CdSe/CdPbScore/thick-shell QDs (a) and PbS/CdS core/shell QDs (b) based LSCs upon UV exposure (1.3 W/cm²) for several hours.

FIG. 13: Normalized PL spectra measured at different optical paths for the thin-film LSCs based on UV and visible C-dots.

FIG. 14: Photographs of large-area water-soluable C-dot based LSCs. (a) under UV illumination (b) transparent LSC (c) flexible.

### DESCRIPTION OF ILLUSTRATIVE EMBODIMENTS

Before the present invention is further described, it is to be understood that the invention is not limited to the particular embodiments described below, as variations of these embodiments may be made and still fall within the scope of the appended claims. It is also to be understood that the terminology employed is for the purpose of describing particular embodiments, and is not intended to be limiting. Instead, the scope of the present invention will be established by the appended claims.

In order to provide a clear and consistent understanding of the terms used in the present specification, a number of definitions are provided below. Moreover, unless defined otherwise, all technical and scientific terms as used herein have the same meaning as commonly understood to one of ordinary skill in the art to which this invention pertains.

As used herein, the term “large-area” as it relates to luminescent solar concentrators (LSCs) refers to the surface of a face of the sheet oriented toward the energy source (input area). Such surface may be in the range of at least about 25 to about 2500 cm².

As used herein, the term “photo-stability” as it relates to luminescent solar concentrators (LSCs) refers to an LSC which when exposed to a radiant energy such as the sun, remains substantially unchanged.

As used herein, the term “surface-modified” as it relates to colloidal quantum dots (C-dots) refers to C-dots having at least some functional groups at the surface that have been transformed to another functional group. For example, C-dots wherein at least some carboxyl groups at the surface have been transformed to amide groups.

The word “a” or “an” when used in conjunction with the term “comprising” in the claims and/or the specification may mean “one”, but it is also consistent with the meaning of “one or more”, “at least one”, and “one or more than one”. Similarly, the word “another” may mean at least a second or more.

As used in this specification and claim(s), the words “comprising” (and any form of comprising, such as “comprise” and “comprises”), “having” (and any form of having, such as “have” and “has”), “including” (and any form of including, such as “include” and “includes”) or “containing” (and any form of containing, such as “contain” and “contains”), are inclusive or open-ended and do not exclude additional, unrecited elements or process steps.

As used herein the term “about” is used to indicate that a value includes an inherent variation of error for the device or the method being employed to determine the value.

The term “alkyl” or “alk” as used herein, represents a monovalent group derived from a straight or branched chain saturated hydrocarbon comprising, unless otherwise specified, from 1 to about 30 carbon atoms and is exemplified by methyl, ethyl, n- and iso-propyl, n-, sec-, iso- and tert-butyl, neopentyl and the like, and may be optionally substituted with one, two, three or, in the case of alkyl groups comprising two carbons or more, four substituents.

The inventors have designed and fabricated a new and improved LSC that uses an emitter comprising non-toxic colloidal carbon quantum dots, also called (non-toxic C-dots or C-QDs). The LSC of the invention is metal-free, large-area, efficient and presents a good photo-stability.

More specifically, the inventors have designed and fabricated a metal-free large-area LSC based on C-dots with good efficiency and photo-stability. First, the C-dots were synthesized via a solvothermal method know in the art, with relatively high PLQY (30%) [38]. The overlap between the absorption and PL spectra of C-dots was decreased by post-surface treatment with oleylamine (OLA) or NaOH, which reduces the absorption of C-dots in the long-wavelength range (550-700 nm).

QDs/PLMA polymer based LSCs were fabricated by using OLA-treated C-dots, and thin-film LSCs were fabricated using NaOH treated C-dots. Hydrophobic OLA-treated C-dots were incorporated into monomer (lauryl methacrylate) for further polymerization with a UV initiator [17,20,22]. Thin-film LSC was fabricated by spin-coating hydrophilic C-dots/polyvinylpyrrolidone (PVP) mixture on the glass substrate. In addition, tandem thin-film LSCs based on C-dots were fabricated by spin-coating a hydrophilic C-dots/polyvinylpyrrolidone (PVP) mixture on a glass substrate.

The lateral area of the as-fabricated thin-film LSCs based on C-dots is 100 cm², which is 25 times larger than that of LSCs based on N-doped C-dots recently reported in the literature [43]. Moreover, the tandem thin-film LSCs based on C-dots with appropriate splitting spectral profiles achieves an external optical efficiency of 1.1%, which is comparable to those of high efficiency large-area LSCs based on inorganic QDs [17-19].

The large-area LSCs based on C-dots according to the invention exhibit a highly transparent (over 90% for wavelengths longer than 500 nm) composite with low reabsorption losses, good optical performance including high external optical efficiency and good photo-stability.

The present invention is illustrated in further details by the following non-limiting examples.

### Example 1—Synthesis and Structure of C-Dots

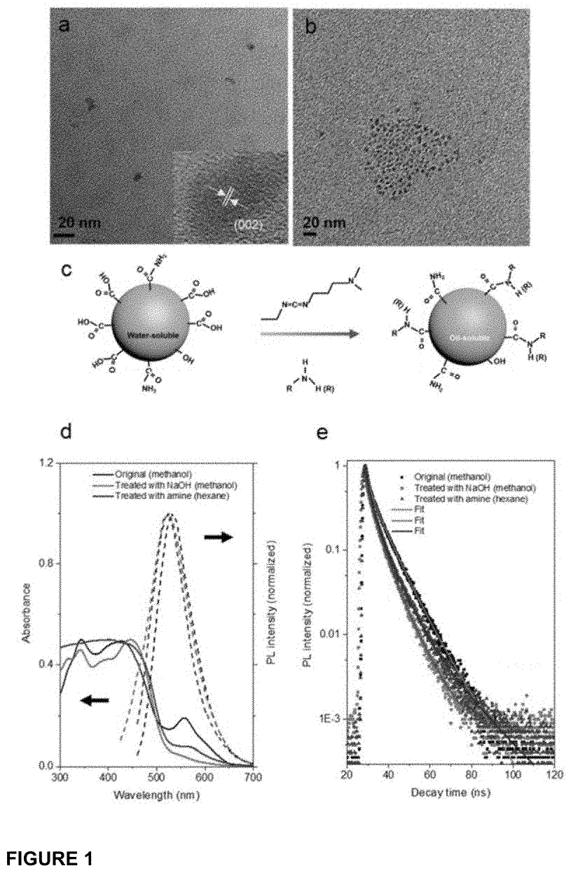

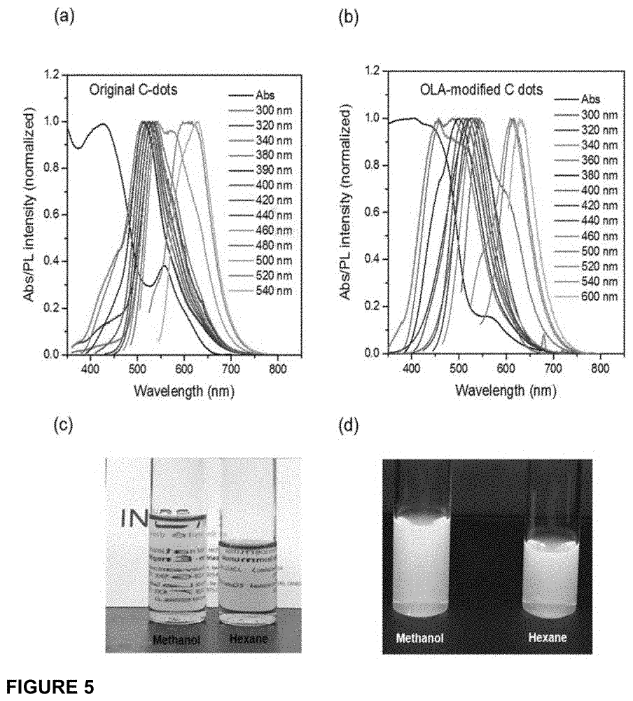

C-dots were synthesized via a solvothermal method using citrate and urea as precursor sources following procedures described in more detail herein below and in the art [38]. The as-synthesized C-dots with absorption spectrum in the UV range were used directly for thin-film LSC fabrication [44]. For C-dots with absorption spectrum extending in the visible range (denoted as visible C-dots) [38], in the presence of 1-ethyl-3-(3-dimethylaminopropyl)carbodiimide (EDC) which acts as catalyst and cross-linker, the primary amine from long carbon-chain molecule OLA reacts with the carboxyl group on the surface of C-dots (FIG. 1c). The OLA-modified C-dots exhibit hydrophobic features due to the long carbon-chain, and can be efficiently dispersed in a nonpolar solvent such as hexane (FIG. 5c). As shown in FIG. 1a, the as-prepared C-dots have diameter sizes in the range of about 5-10 nm, which is consistent with values reported in the art [38]. The high resolution transmission electron microscopy (HRTEM) image displayed in the inset of FIG. 1a identifies a lattice spacing of about 0.333 nm well indexed to the (002) plane of graphite, demonstrating the graphitic sp² character of the C-dots, which contributes to strong band edge emission other than lower energy emission from surface traps [37,38]. After surface modification using OLA and further dispersion in hexane, the size and morphologies of C-dots remain unchanged (FIG. 1b), suggesting a successful phase transfer of C-dots from polar to nonpolar solvent. As can be seen on the pictures in FIG. 5c, the solution of C-dots appears clear both in methanol and hexane, indicating good a dispersity before and after phase transfer.

### Example 2—Optical Properties of C-Dots

The absorption and PL spectra of C-dots before and after different surface treatments are reported in FIG. 1d. For a fair comparison, all the C-dots were measured under identical conditions e.g. same concentration, optical path and excitation wavelength. The spectrum acquired from freshly synthesized C-dots shows a strong absorption extended over the entire window of visible wavelengths. However, the absorption spectrum strongly overlaps with its broad PL spectrum (500-600 nm) which indicates a large overlap between absorption and emission spectra (FIG. 1d). Metal-cation-functionalized C-dots (surface treatment with NaOH) decreases this overlap, resulting in a lower reabsorption (FIG. 1d). We compared the optical performance under different treatments with NaOH or OLA. After treatment with NaOH, the surface of C-dots is passivated by Na⁺, thereby reducing electron transitions from surface states minimizing the absorption of C-dots in the range of 550-700 nm range (FIG. 1d) [38]. As reported by Qu et al., the efficiency in Na⁺-capped C-dots based light emitting device (LED) exhibits an improvement compared to the LED based on the original C-dots, due to the efficient metal ion surface passivation and large Stokes-shift [38].

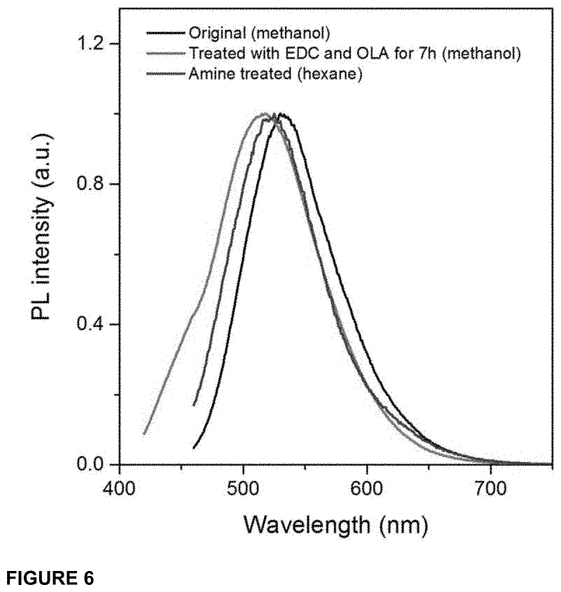

The OLA-modified C-dots maintain a strong absorption in this range (300-500 nm) and simultaneously exhibit a reduced absorption in the 550-700 nm range (FIG. 1d). The C-dots before and after OLA-treatment exhibit an excitation-wavelength dependent PL spectrum (FIGS. 5a and 1b). With the increase of the excitation wavelength, the PL peak of C-dots exhibits a red-shift. As the absorption spectrum does not change, the red-shift of PL peak leads to a smaller overlap of the absorption and emission spectra, which is promising for their applications in LEDs [38] and LSCs. After phase transfer, the C-dots still exhibit bright emission under UV illumination (FIG. 5d). The reduced re-absorption and oil-soluble property of the OLA-modified C-dots are promising for LSC fabrication. The PLQY of the Na⁺-modified C-dots is around 40%, which is higher than that of freshly prepared C-dots (about 30%) and of OLA-modified C-dots (about 20-30%) [38]. The OLA-modified C-dots exhibit a similar PL emission peak as that of a freshly prepared sample (FIG. 6). Considering that the modification process is carried out under ambient conditions without any protection, C-dots present a better chemical/structural stability compared to other types of inorganic QDs [17-23].

PL decay curves of C-dots with different treatments were also studied, as shown in FIG. 1e. Due to the well passivated surface treatment, the PL lifetime of Na⁺-modified C-dots is about 7.1±1 ns, which is in the same range with the value reported in the art for high-efficiency Na⁺ C-dots (about 4 ns) [38]. The PL lifetime of the original and OLA-modified C-dots is around 8.6±1 ns, which is longer than that of NaOH-treated C-dots, and is consistent with the PLQYs reported in the art [38].

### Example 3—C-Dot Based LSCs

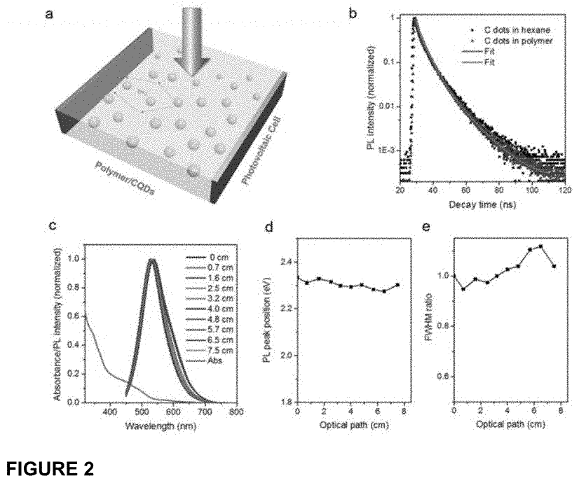

First, we focus on fabricating large-area LSCs by incorporating hydrophobic OLA-modified C-dots in the poly(lauryl methacrylate) (PLMA) polymer matrix. Details on LSC fabrication are presented herein below. After polymerization with a UV initiator, C-dots were embedded into a cross-linked PLMA polymer matrix with typical dimensions of 0.2×1.5×10 cm³ [17]. The absorption and PL spectra of the C-dots in the PLMA polymer matrix are almost identical to those of the C-dots in hexane (FIGS. 1d and 2c). The working principle for C-dot based LSCs in polymer matrix is illustrated in FIG. 2a.

The absence of additional non-radiative decay channels in the C-dots/polymer was confirmed by PL decay measurements, which showed identical dynamics for the C-dots in hexane and after encapsulation in the polymer (FIG. 2b). We further measured the PL spectra of C-dots based LSCs as a function of the optical path (FIG. 2c). Specifically, the PL signals from the LSC are recorded at a certain distance between the edge and vertically illuminated spot at an excitation wavelength of 440 nm, which characterizes the reabsorption effect on LSCs. As shown in FIG. 2c, the overlap between absorption and emission spectra is small. By increasing the optical path, the PL spectra exhibits a limited red-shift. Following the approach introduced by Meinardi et al. [18], we normalized the PL spectra of LSCs as a function of optical paths. The PL peak position and shape can be affected by the light reabsorption by either polymer matrix or C-dots [18]. The PL peak position is almost unchanged, remaining close to 2.3 eV (about 540 nm) due to the efficient separation between the absorption and emission spectra [18,19], indicating that the OLA-modified C-dots based LSC exhibits a good optical performance (FIG. 2d). Only a slight PL peak tail was observed for long optical paths (>5 cm), leading to a broadening of the PL FWHM, which is due to reabsorption (FIG. 2e).

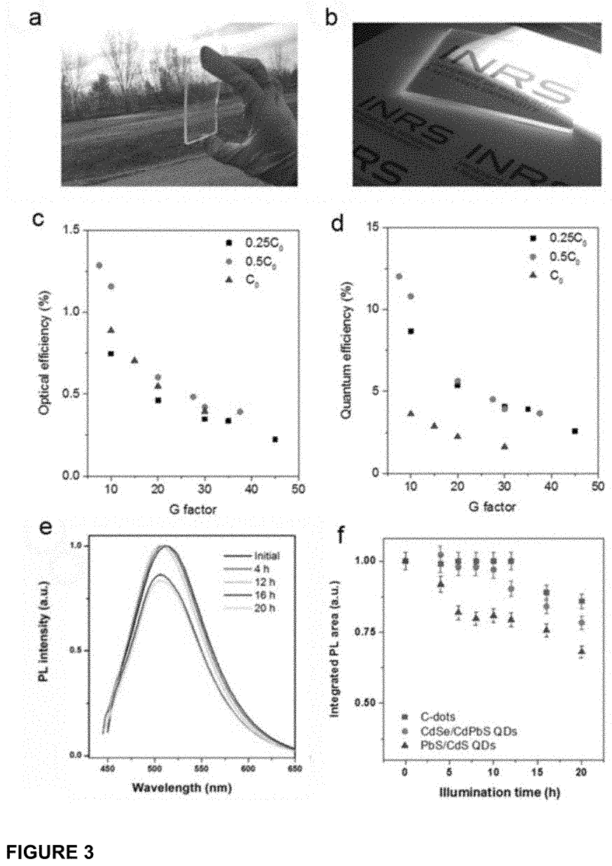

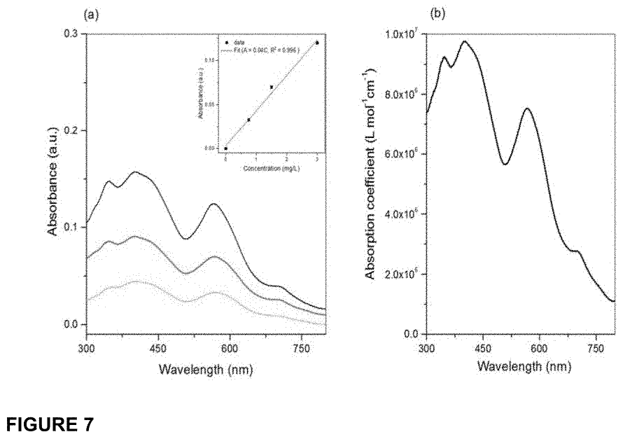

As shown in FIG. 3a, the square large-area LSC (10×10 cm²) appears highly transparent in ambient environment, and a concentrated yellow light is visible under low-intensity illumination (0.3 Sun, 30 mW/cm²) (FIG. 3a), indicating the promising potential to be used to power buildings even when the light intensity is reduced, for example when the sky is overcast. When the top surface of the LSC is partially placed under one sun illumination, the concentrated yellow light emitting from the edges is visible, as can be seen in FIG. 3b. The optical performance of the planar LSCs with different concentrations of C-dots (absorption spectra of C-dots are shown in FIG. 7, which were used to define the concentration of C-dots in PLMA) of C-dots (dimension: 0.2×1.5×10 cm³) are shown in FIGS. 3c-f. To calculate the external optical efficiency of the LSCs, we coupled a commercial Si solar cell on one edge of the OLA-modified C-dot based LSCs (details described herein below and in the art) [12,17,20]. The external optical efficiency (ηₒₚₜ) can be defined as

$${η}_{opt} = \frac{{I}_{LSC} \times {A}_{PV}}{{I}_{SC} \times {A}_{LSC}} = \frac{{I}_{LSC}}{{I}_{SC} \times G} \qquad ( 1 )$$

where I_{LSC} is the short circuit current generated by the Si solar cell coupled to the LSC and I_{SC} is the short circuit current of the cell under direct illumination; the geometric (G) factor is defined as the ratio of top surface area of the LSCs and the active area of the solar cell [10].

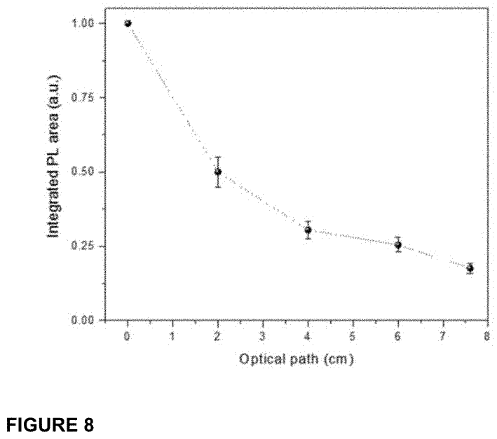

As expected, we noted a drop of ηₒₚₜ with the increase of the G factor of the LSCs (FIG. 3c), which is consistent with the decrease of integrated PL area with the increase of optical paths (FIG. 8). This may be due to the combined effect of light escaping from the waveguide and reabsorption by the C-dots and the polymer matrix. A maximum external optical efficiency of ηₒₚₜ˜1.2% (ηₒₚₜ of about 1.2%) is achieved with a G factor of 10 (1.5×2 cm², three edges coupled with optical mirror) at a concentration of 0.5 C₀ (C₀ equals to 2.8 mg/L) (FIG. 3c). Increasing the G factor to up to 38, ηₒₚₜ decreased to about 0.4%, due to reabsorption and scattering loss. The internal quantum efficiency (η_{quantum}, also called collection efficiency) is an important parameter of an LSC, which is defined as the ratio of number of photons collected by solar cell and the number of incident photons absorbed by fluorophores in LSCs.

We further estimated the quantum efficiency η_{quantum} of the LSCs using the following equation:

$${η}_{quantum} = \frac{{I}_{LSC}}{{I}_{SC}^{Abs} \times G} \qquad ( 2 )$$

where I_{SC}^{Abs} is the short circuit current generated by a Si solar cell under an illumination equal to the light absorbed by the C-dots.

In this case, the highest η_{quantum} was achieved by the LSC with the lower concentration (0.5 C₀) of C-dots, with a value of about 13%, slightly lower than the PLQY of the C-dots in hexane. This data indirectly confirms that the PL emission of embedded C-dots does not change when embedded in the polymer matrix. The highest value obtained for 0.25 C₀ may be due to the smallest absorption at this concentration in the emission range of the C-dots which limits the energy loss due to re-absorption [40]. Even at a large G factor (G=38), η_{quantum} is still around 4%. This value is similar to that of LSCs made of PbS/CdS core/shell QDs (4.5%, G=50) known in the art [17]. Comparing η_{quantum} of the C-dot based LSCs with the best inorganic QDs based LSC, we observe that the internal quantum efficiency obtained using CdSe/CdS core/shell QDs with a QY of 45% (measured under the same conditions, under one sun and the same distance from the sun simulator to the LSCs) is around 10% at G=40 [19]. With a higher PLQY of about 70% for the same type of CdSe/CdZnS core/shell QDs, the maximum internal quantum efficiency increases to 15% at G=32 [45]. Using CuInSeₓS₂₋ₓ/ZnS core/shell QDs, η_{quantum} is about 16.7% [18]. Considering the much lower PLQY (about 20-30%) in C-dots compared to the valu reported in the art for inorganic QDs, the reported quantum efficiency is comparable to those of semi-transparent efficient inorganic QD based LSCs (Table 1 below).

TABLE 1
Optical performance of QDs based LSCs.

| | | | | Optical | Quantum | |
|---|---|---|---|---|---|---|
| | PLQ | Lateral | | effi- | effi- | |
| Sample | Y | area | G | ciency | ciency | |
| (QDs) | (%) | (cm²) | Factor | (%) | (%) | Ref. |
| C-dots | 30 | 1.5 × 8 | 38 | 0.4 | 4 | Present |
| (polymer | | | | | | inven- |
| based) | | | | | | tion |
| PbS/CdS | 40 | 1.5 × 10 | 50 | 1.1 | 4.5 | [1] |
| CdSe/CdS | 45 | 1.3 × 21.5 | 40 | 1 | 10 | [2] |
| CdSe/CdZnS | 70 | 20 × 20 | 32 | 0.9 | 15 | [3] |
| CuInSeₓS₂₋ₓ/ | 40 | 12 × 12 | 40 | 2.85 | 16.7 | [4] |
| ZnS | | | | | | |
| N-doped C- | — | 2.5 × 1.6 | 4.88 | 4.75 | — | [5] |
| dots (thin film | | | | | | |
| on a glass) | | | | | | |

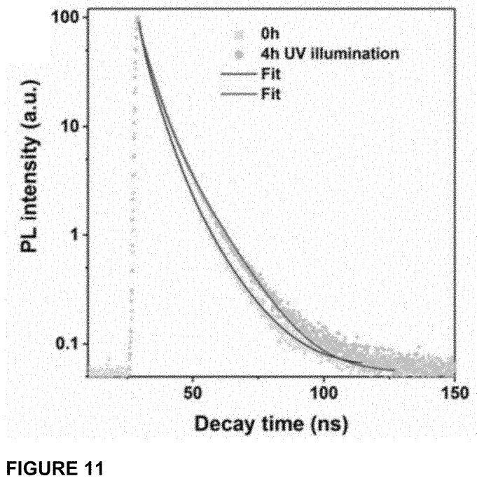

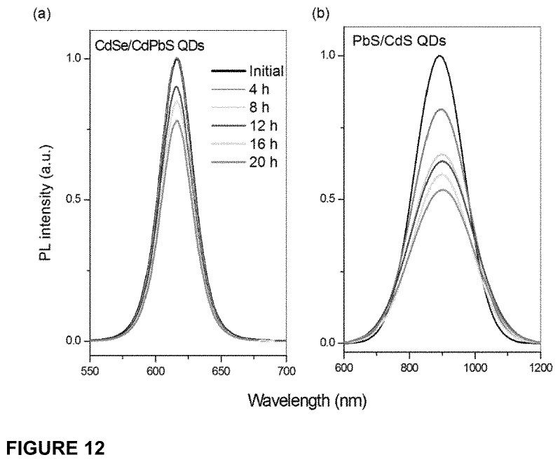

We further examined the stability of LSCs based on various types of QDs including PbS/CdS core/shell QDs [17], CdSe/CdPbS core/thick-shell QDs [20] and C-dots under identical measurement conditions (a high dose of UV illumination, 1.3 W/cm², equal to 260 sun illumination [45]; humidity of about 40% at room temperature). After four hours, the PL peak position and PL intensity of the as-fabricated LSCs based on C-dots and CdSe/CdPbS core/thick-shell QDs do not show a significant change compared to the LSC before illumination (FIGS. 3e and 3f). Similarly, the PL lifetime of C-dots in polymer matrix exhibit equivalent values of 7.2±1 ns and 8.6±1 ns after and before 4 hours of UV exposure, respectively (FIG. 11). When increasing the illumination time (12 hours), the PL intensity of LSCs based on C-dots still does not change, indicating the LSCs based on C-dots are photo-stable [45]. While further UV illumination (12 hours) leads to a decrease in PL intensity of the LSCs based inorganic QDs (such as 20% drop in PbS/CdS QDs and 10% drop CdSe/CdPbS QDs) (FIGS. 3f and 12). In addition, there is no significant change regarding the color and external optical efficiency of the LSCs based on C-dots after storing at ambient conditions for more than four months. These results indicate that C-dots QDs based LSCs are promising for long-term stable LSCs application compared to inorganic QDs based LSCs.

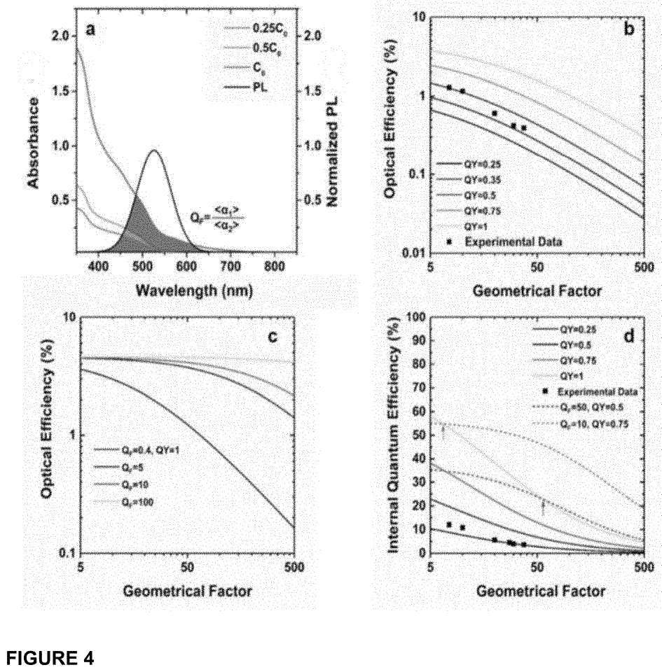

To validate our measurements and explore the possibility of realizing large-area LSCs with C-dots exhibiting higher PLQY, we implemented the analytical model of planar LSCs reported in the art [19] (details for simulation are outlined herein below). Considering that the model was developed for semiconducting QDs, we can still accurately fit the results of the ηₒₚₜ and internal quantum efficiency as reported in FIGS. 4b and 4d. In addition, we can simulate the effect of increasing the PLQY of the C-dots (Table 2 below): with a PLQY value of 75% the maximum optical efficiency, at G=10, would be around 2% and for G=40 it would be 1%. An ideal C-dot, with PLQY of 1, would have a maximum efficiency of about 3.5% at G=10.

TABLE 2
External optical efficiency of 0.5 C₀ C-dot based
LSC for different values of the PLQY.

| PLQY (%) | G | External optical effciency (%) |
|---|---|---|
| 75 | 10 | 2.5 |
| 75 | 40 | 1.5 |
| 100 | 10 | 3.5 |

Another way to increase the performance of the LSC is to increase the quality factor (Q_{F}) defined as the ratio between the absorption coefficient (α₁) at the wavelength λ₁ of collected light and the absorption coefficient (α₂) at the emission peak (FIG. 4a).

FIG. 4c reports simulation results of the effect of increasing Q_{F} (and therefore indirectly the Stokes-shift) of the C-dots with PLQY=1 on the optical efficiency. The main consequence is an increase of the efficiency for large-area LSCs: with a Q_{F} of 10, the maximum efficiency at G=500 would be more than 2%. Considering the large G factor of 500, an efficiency of 2% in LSC leads to at least 10-fold decrease of solar cell area with similar power generation. Observing the internal quantum efficiency (FIG. 4d), the C-dots based LSC would have the same performance as the inorganic QD based LSCs, with a η_{quantum} of about 15% at G=50 when the PL QY of the C-dots is 75%.

It is also possible to mitigate the effect of a low PLQY by an increase of the Q_{F}. For example, with a PLQY=75% and Q_{F}=10 we can achieve higher efficiency than in the case of C-dots with an ideal PLQY=100% but lower Q_{F}. A similar performance of LSCs could be achieved by using C-dots (G=50) with either a PLQY of 50% (Q_{F}=50) or a PLQY of 100% (Q_{F}=0.4). This simulation indicates that we can tune both the PLQY and the Q_{F} by tuning the concentration of C-dots and the overlap of absorption and emission spectra to obtain high-efficiency C-dot based LSCs.

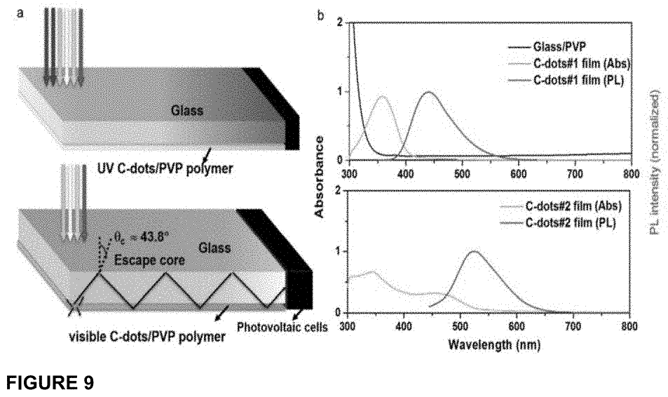

To demonstrate the suitability of C-dots as emitters in LSCs, we further fabricated LSCs based on a thin-film tandem system by incorporating hydrophilic C-dots in the PVP and spin-coating them on the glass substrate (scheme in FIG. 9a). Compared to the above-mentioned QDs/PLMA polymer based LSCs which has thickness of 2 mm, the thickness of C-dots/PVP layer on a glass substrate is only 50-100 μm. The emitted photons travel within the glass, decreasing the probability of meeting C-dots, leading to reduced energy loss due to the reabsorption. In addition, only NaOH post-surface treatment is needed as visible C-dots can be effectively dispersed in PVP/methanol or PVP/water. Moreover, the fabrication technique used for realizing large-area LSCs is simple and no organic solvent and UV illumination are used. Two types of C-dots were used to fabricate the LSCs. The first layer of LSCs was fabricated using UV C-dots (denoted as #1) [44] (PLQY of 60%) without post-surface-treatment. The visible NaOH modified C-dots (denoted as #2) with a QY of 40% and the original C-dots without surface treatment (PLQY of about 30%) were used to fabricate the second layer of thin-film LSCs (FIGS. 9a and 9b).

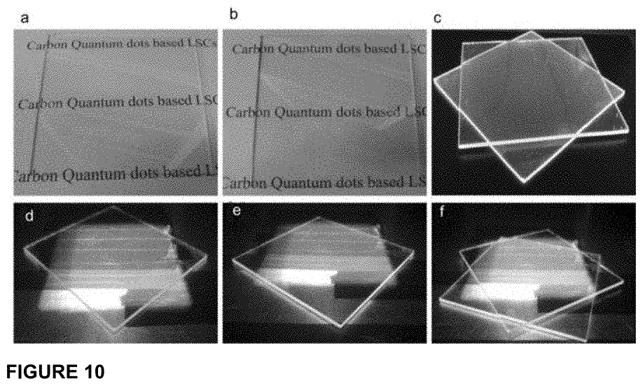

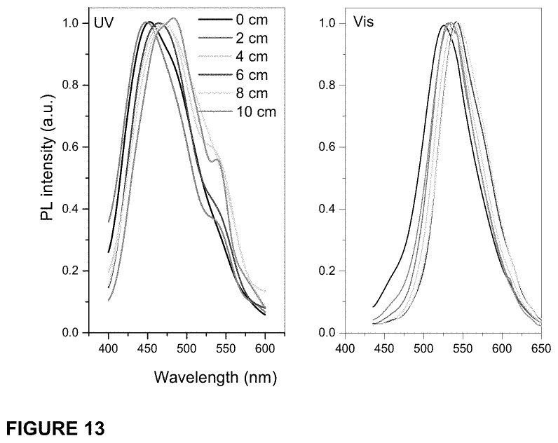

As shown in FIG. 9b, UV C-dots exhibit large separation of absorption and emission spectra and a high PLQY of 60%, which reduces the reabsorption loss. In addition, the emitted visible light in the first layer escaped by the waveguide, could be further absorbed by the second layer of NaOH treated C-dots, concentrating from the edges of the glass substrate. By using UV and visible NaOH modified C-dots, we fabricated semitransparent tandem thin-film LSCs, shown under different illuminations (FIG. 10). Thin film C-dots based LSCs exhibit a good transparency in visible range, which is favorable for the use of solar windows (FIGS. 10a and 10b). The PL peak position for both types of C-dots exhibits a slight red-shift due to the reabsorption energy loss (FIG. 13). The optical performance of thin-film LSCs under solar radiation (100 mW/cm²) was directly measured by an optical power meter. Single layer LSCs have an optical efficiency (measured as the ratio of output power of LSCs collected from edges and solar input power through top surface) of 0.4% and 0.9%, respectively for UV C-dots based LSC and visible NaOH-treated C-dots based LSC, while the tandem thin-film LSC exhibits an optical efficiency of 1.1% with dimension of 10×10×0.2 cm³ due to the reduced scattering and reabsorption (values reported in Table 3 below). The external optical efficiency is comparable with LSCs based on PLMA polymer (1.3%, G of 10), but with a larger surface area (100 cm² vs 3 cm²) [43]. In the art, the external optical efficiency of the LSC with lateral area of 400 cm² is about 0.9% [45], which is similar to that of the tandem thin-film large-area LSCs based on C-dots according to the invention. However, in the art, the hydrophobic Cd-based QDs need to be coated with a silica layer and then dispersed in PVP matrix which is time-consuming and expensive.

TABLE 3
Optical efficiency of thin-film C-dots based glass LSCs with lateral area
(10 × 10 cm²). #1: UV C-dots; #2: visible NaOH treated C-dots.

| LSCs | | Optical efficiency (%) | |
|---|---|---|---|
| C-dots#1 | | 0.4 | |
| C-dots#2_Original | | 0.7 | |
| C-dots#2 | | 0.9 | |
| Tandem LSCs | C-dots#1 | 0.4 | 1.1 in total |
| | C-dots#2 | 0.7 | |

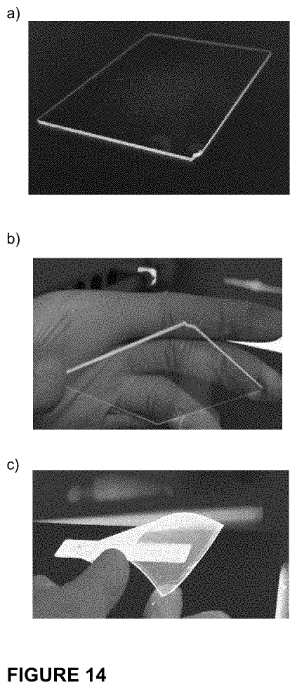

As described above, we can coat the C-dots on the glass and flexible acrylic polymer by spay deposition or spin coating approaches, which allow us to obtain large-area high efficiency LSCs based on C-dots (FIG. 14).

### Discussions

The invention provides for low-cost, large-area and high-efficiency LSCs based on metal-free, colloidal C-dots dispersed in a PLMA polymer matrix or PVP on glass substrate. With proper surface modification, the as-synthesized C-dots show a reduced absorption/PL spectral overlap. The OLA-modified C-dots exhibit a PLQY of about 30% and a good photo-/chemical stability without emission loss during the process of their encapsulation into a polymer matrix. Due to their broad absorption and relatively low reabsorption loss, large-area C-dot based LSCs exhibit an ηₒₚₜ of 1.2% (G=10) and η_{quantum} of 4% (G=38), comparable to those of semi-transparent highly efficient inorganic QD based LSCs. The tandem semi-transparent thin film LSCs (100 cm²) exhibit an external optical efficiency of 1.1%.

The LSCs according to the invention are stable in air and do not exhibit any noticeable variation in PL under UV light illumination (1.3 W/cm²) for over 12 hours. In embodiments of the invention, the external optical efficiency of LSCs may further be enhanced by improving the absorption range, enhancing the PLQY and increasing the quality factor by various modifications to the surface of C-dots. The cost of C-dots based LSCs would be cheaper compared to LSCs made of inorganic QDs, considering the easier synthesis using abundant and low-cost carbon elements and their simple disposal after use. In view of the simple synthesis procedure, easy surface modification, environmental friendliness, non-toxicity, low-cost and good optical properties of C-dots compared to conventional inorganic QDs and dyes/polymers, they may represent a practical emitter for large-area, high efficiency LSCs, which are promising for renewable and clean solar energy applications such as transparent solar windows.

As will be understood by a skilled person, C-dots used in the present invention may also be synthesized by other suitable method.

C-dots surface modification yields surface-modified C-dots that are more efficiently transferred from a polar solvent into a nonpolar solvent. In embodiments of the invention, a long carbon-chain amine, oleylamine is used to convert the carboxyl groups at the surface of the C-dots to amides (FIG. 1c). As will be understood by a skilled person, any other suitable amine may also be used. Such amines include for example amines having a carbon chain of more than about 6 carbons. Also as will be understood by a skilled person, other suitable modifications directed towards other groups at the surface of the C-dots, may be made. For example, modifications may be directed towards hydroxyl groups.

### Example 4—Synthesis of C-Dots

The C-dots were prepared following procedures disclosed in the art [38]. Typically, for visible C-dots, 1 g citric acid and 2 g urea were dissolved in 10 mL dimethylformamide under stirring. Subsequently the precursors were transferred into an autoclave and allow to react for 6 hours at 160° C. After cooling to room temperature, the mixture was then added dropwise to 50 mL hexane to precipitate the C-dots. The precipitates were collected and dispersed in 60 mL methanol (original C-dots in methanol). For the Na⁺ treatment, the original product was mixed with 20 mL NaOH aqueous solution (50 mg/mL), stirred for 1 minute. The mixture was then added dropwise to 50 mL hexane to precipitate the C-dots. The precipitates were dispersed in 60 mL methanol. The purified solution was transferred into dialysis bags with a molecular weight of 3000 Da for 2 hours. The C-dots/methanol solution inside the dialysis bag was collected by opening the dialysis bag and pouring the solution into a plastic tube.

In the case of the OLA-modified C-dots, 5 mL as-prepared C-dots in methanol were added to 250 mg EDC and 1 mL OLA. The mixture solution was then stirred for 15 hours at room temperature. After the reaction, 20 mL of additional hexane were then fully mixed with the aforementioned solution. The OLA-modified C-dots were transferred into hexane after 5 minutes standing. For purification of OLA-modified C-dots, the product was kept at −10° C. for 1 hour. With low temperature, the residue OLA was precipitated and removed.

For UV C-dots, 1.051 g citric acid and 335 μL ethylenediamine were dissolved in 10 mL water under stirring. Subsequently the precursors were transferred into an autoclave and allow to react for 6 hours at 200° C. The as-synthesized reaction solution was transferred into dialysis bags with molecular weight (MW) of 3000 Da for 2 hours. The C-dots methanol solution outside the dialysis bag was collected and concentrated to 15 mg/L [44].

### Example 5—Device Fabrication and Measurement

LSCs Based on C-Dots/PLMA Matrix.

The LSCs were fabricated by embedding the C-dots in the polymer matrix. OLA-modified C-dots dispersed in hexane were added to a 50 mL flask and the solvent vapor was pumped away. The monomer precursors of lauryl methacrylate and ethylene glycol dimethacrylate (wt % of 5:1) and a UV initiator (diphenyl(2,4,6-trimethylbenzoyl)phosphine oxide were mixed and sonicated until a colourless solution was obtained. The solution was then transferred into the flask containing the solvent-free C-dots. The mixture was homogeneously dispersed by ultrasound treatment, then injected into a mold consisting of two glass slides separated by a flexible silicon rubber spacer of thickness about 2 mm. The mixture was kept under UV illumination (Luzchem LZC-ICH2, λ=420 nm, dose 3 W/cm²) for 2 hours.

LSCs Based on C-Dots/PVP Thin Film on a Glass Substrate.

The C-dots dispersed in methanol were mixed with PVP polymer with a final concentration of PVP of 200 mg/mL. The concentration of C-dots is around 15 mg/mL. Then the mixture was spin-coated with a speed of 500 rpm and an acceleration rate of 800 rpm for 1 minute on a glass substrate (10×10 cm²) with a thickness of 50-100 μm. The thickness of the glass is around 2 mm.

LSCs Based on Inorganic QDs/Polymer Matrix.

PbS/CdS QDs and CdSe/CdPbS QDs were synthesized based on our previously reported approach [17,20]. The LSCs based on PbS/CdS QDs and CdSe/CdPbS QDs were fabricated by embedding the QDs in the polymer matrix. The as-fabricated LSCs based on PbS/CdS QDs and CdSe/CdPbS QDs with dimension of 2×2 cm² were used for stability measurements [17,20].

Materials Characterization.

TEM characterization of the C-dots was carried out using a JEOL 2100F TEM. Absorption spectra were acquired with a Cary 5000 UV-vis-NIR spectrophotometer (Varian) with a scan speed of 600 nm/min. Fluorescence spectra were acquired with a Fluorolog-3 system (Horiba Jobin Yvon). The PL lifetime of the C-dots in solution and in the polymer matrix was measured using a pulsed laser diode of 440 nm and Time-Correlated Single Photon Counting (TCSPC) mode in the Fluorolog-3 system. The PL intensity of LSCs based on different types of QDs (C-dots, PbS/CdS QDs and CdSe/CdPbS QDs) was measured by PL spectroscopy upon UV illumination (1.3 W/cm² measured by a power meter, Newport Model 843-R) under ambient conditions.

Optical Measurement of LSCs.

The external optical efficiency of the LSCs based on C-dots/PLMA was measured by using an ABET2000 solar simulator at AM 1.5G (100 mW/cm²) calibrated using a reference Si solar cell. LSCs were prepared with different lengths and their external optical efficiency was tested by illuminating the full area of the LSC, with one edge mounted with a Si solar cell and the other three edges and bottom facing to commercial mirrors, as illustrated in previous work [17,20]. The Si solar cell used was a commercial model (IXYS KXOB22). Since the total area of the Si cell is larger than the edge area of the LSC, a black tape was used to mark the excessive area of the cell and leave an exposed surface of 0.3 cm² (same as the edge of the LSC). The performance parameters of the cell are as follows: PCE=4.65%, J_{SC}=20.3 mA/cm², V_{OC}=0.51 V, FF=0.45. The current-voltage (I-V) characteristics of the Si solar cell, laterally coupled to the LSC, were measured by a Keysight 2900A SourceMeter. The external optical performance of thin-film LSCs based on C-dots/PVP was measured by using optical power meter (Newport Model 843-R), when the LSC with edges exposed was illuminated under simulated sunlight. For the measurement of tandem thin-film LSCs, two LSCs were placed with an air gap of 2 cm.

Analytical Model for Efficiency Simulation of LSC with C-Dots

Following the formalism developed in [42] we could calculate the efficiency of the LSC as:

$${η}_{optical} = \frac{1.05 \cdot ( 1 - R ) ( 1 - {e}^{- < {α}_{1} > d} ) {η}_{PL} {η}_{TIR}}{1 + {βα}_{2} L ( 1 - {η}_{PL} {η}_{TIR} )} \qquad ( 3 )$$

in which <α₁> is the spectrally averaged absorption coefficient, d is the thickness of the LSC, η_{PL} is the estimated PLQY of the C-dots, fixed to 0.25; η_{TIR} is the total internal reflection efficiency of the polymer waveguide that can be estimated to be around 75% [20]; β is a numerical value fixed to 1.4 as in [42], α₂ is the absorption coefficient at the wavelength λ₂, peak of the emitted light; R is fraction of the incident light reflected by the collecting surface estimated to be 3% [20].

To correct the underestimation of the overall efficiency resulting from neglecting effects of reabsorption/reemission within the escape cone, we introduced a correction factor of 5%.

Since our experimental data on external optical efficiency have been obtained under simulated solar light with non-monochromatic spectrum, we used a spectrally averaged absorption coefficient <α₁> defined as:

$$< {α}_{1} >= - \frac{1}{d} ln ( \frac{{\int }_{0}^{∞} {S}_{in} ( λ ) λ {e}^{- α ( λ ) d} d λ}{{\int }_{0}^{∞} {S}_{in} ( λ ) λ d λ} ) \qquad ( 4 )$$

in which and a is the absorption coefficient and Sᵢₙ is the solar irradiance at 1.5G.

To obtain a better fit of the experimental data, α₂ can be replaced by its average valued <α₂>. In this way it is possible to take into account the variation of the absorption coefficient along the emission band. <α₂> can be determined as follows:

$$< {α}_{2} >= \frac{\int {S}_{PL} ( λ ) α ( λ ) d λ}{\int {S}_{PL} ( λ ) d λ} \qquad ( 5 )$$

in which S_{PL}(λ) is the PL emission spectrum.

From formula (1) it is also possible to obtain the internal quantum efficiency as:

$${η}_{quantum} = \frac{{η}_{PL} {η}_{TIR}}{1 + β < {α}_{2} > L ( 1 - {η}_{PL} {η}_{TIR} )} \qquad ( 6 )$$

### Example 6—Thin Film Based LSCs

C-dots dispersed in methanol were mixed with a polymer (polyvinylpyrrolidone (PVP) or poly(vinyl alcohol), polyethylene glycols with average mol. wt. 1,000-1,000,000) with weight concentration of 60-500 mg/mL to form a homogeneous C-dots/polymer solution. The concentration of C-dots in the polymer/methanol solution is 5-100 mg/mL. C-dots/polymer mixture is placed on a glass substrate or poly(methyl methacrylate) (PMMA) substrate by spray deposition or spin coating (1000 rpm for 1 minute).

### DISCUSSION

The LSCs according to the invention are fabricated by embedding the C-dots in a polymer matrix. This may be performed by mixing the C-dots with monomers material and conducting a polymerization reaction using an initiator such as a photo-initiator. Alternatively, the C-dots may be mixed directly with a polymer material. The C-dots may also be mixed with a pre-polymer or precursor polymer material.

The monomers material may comprise one or more types of monomer including but not limited to alkyl acrylates for example alkyl acrylates having about 4-12 carbon atoms in the alkyl group or alkyl acrylates having an average of about 4-12 carbon atoms in their alkyl groups (CH₂═C(CH₃)COOCH₂(CH₂)ₙCH₃ wherein n=4-12, CH₂═C(H)COOCH₂(CH₂)ₙCH₃ wherein n=4-12) and alkyl methacrylates such as ethylene glycol dimethacrylate (EGDM) and lauryl methacrylate.

As will be understood by a skilled person, the polymer matrix according to the invention and as described above may be rigid or flexible. Also, in embodiments of the invention wherein a substrate coated with the mixture C-dots/polymer is used, such substrate may be rigid or flexible.

The luminescent solar concentrators (LSCs) according to the invention are “large-area” LSCs. Indeed, the surface of a face of the sheet (or matrix or coated substrate) oriented toward the energy source (input area) may be in the range of at least about 25 to about 2500 cm².

The scope of the claims should not be limited by the preferred embodiments set forth in the examples, but should be given the broadest interpretation consistent with the description as a whole.

The present description refers to a number of documents, the content of which is herein incorporated by reference in their entirety.

### REFERENCES

1. R. Adhikari, L. Jin, F. Navarro-Pardo, D. Benetti, B. AlOtaibi, S. Vanka, H. Zhao, Z. Mi, A. Vomiero, F. Rosei, Nano Energy (2016) 27, 265.
2. Y. Zhou, M. Celikin, A. Camellini, G. Sirigu, X. Tong, L. Jin, K. Basu, X. Tong, D. Barba, D. Ma, S. Sun, F. Vidal, M. Zavelani-Rossi, Z. M. Wang, H. Zhao, A. Vomiero, F. Rosei, Adv. Energy Mater. (2017) 1602728.
3. X. Tong, Y. Zhou, K. Basu, R. Adhikari, G. S. Selopal, X. Tong, H. Zhao, S. Sun, A. Vomiero, Z. M. Wang, F. Rosei, Nano Energy (2016) 31, 441.
4. Y. Tachibana, L. Vayssieres, J. R. Durrant, Nat. Photon. (2012) 6, 511.
5. G. S. Selopal, H. Zhao, X. Tong, D. Benetti, F. Navarro-Pardo, Y. Zhou, D. Barba, F. Vidal, Z. M. Wang, F. Rosei, Adv. Funct. Mater. (2017) 27, 1701468.
6. I. Statistics, Key World Energy Statistics, International Energy Agency, France 2014.
7. Y. Cui, C. M. Lieber, Science (2001) 291, 851.
8. G. D. Gutierrez, I. Coropceanu, M. G. Bawendi, T. M. Swager, Adv. Mater. (2016) 28, 497.
9. N. D. Bronstein, L. Li, L. Xu, Y. Yao, V. E. Ferry, A. P. Alivisatos, R. G. Nuzzo, ACS Nano (2014) 8, 44.
10. F. Purcell-Milton, Y. K. Gun'ko, J. Mater. Chem. (2012) 22, 16687.
11. V. Sholin, J. D. Olson, S. A. Carter, J. Appl. Phys. (2007) 101, 123114.
12. H. Zhao, Y. Zhou, D. Benetti, D. Ma, F. Rosei, Nano Energy (2017) 37, 214.
13. M. G. Debije, P. P. C. Verbunt, Adv. Energy Mater. (2012) 2, 12.
14. S. Kalytchuk, S. Gupta, O. Zhovtiuk, A. Vaneski, S. V. Kershaw, H. Fu, Z. Fan, E. C. H. Kwok, C-F. Wang, W. Y. Teoh, A. L. Rogach, J. Phys. Chem. C (2014) 118, 16393.
15. M. K. Mahata, S. P. Tiwari, S. Mukherjee, K. Kumar, V. K. Rai, J. Opt. Soc. Amer. B (2014) 31, 1814.
16. U. Rau, F. Einsele, G. C. Glaeser, Appl. Phys. Lett. (2005) 87, 171101.
17. Y. Zhou, D. Benetti, Z. Fan, H. Zhao, D. Ma, A. O. Govorov, A. Vomiero, F. Rosei, Adv. Energy Mater. (2016) 6, 1501913.
18. F. Meinardi, H. McDaniel, F. Carulli, A. Colombo, K. A. Velizhanin, N. S. Makarov, R. Simonutti, V. I. Klimov, S. Brovelli, Nat. Nanotechnol. (2015) 10, 878.
19. F. Meinardi, A. Colombo, K. A. Velizhanin, R. Simonutti, M. Lorenzon, L. Beverina, R. Viswanatha, V. I. Klimov, S. Brovelli, Nat. Photon. (2014) 8, 392.
20. H. Zhao, D. Benetti, L. Jin, Y. Zhou, A. Vomiero, F. Rosei, Small (2016) 12, 5354.
21. R. H. Inman, G. V. Shcherbatyuk, D. Medvedko, A. Gopinathan, S. Ghosh, Opt. Express (2011) 19, 24308.
22. I. Coropceanu, M. G. Bawendi, Nano Lett. (2014) 14, 4097.
23. C. S. Erickson, L. R. Bradshaw, S. McDowall, J. D. Gilbertson, D. R. Gamelin, D. L. Patrick, ACS Nano (2014) 8, 3461.
24. C. Li, W. Chen, D. Wu, D. Quan, Z. Zhou, J. Hao, J. Qin, Y. Li, Z. He, K. Wang, Sci. Rep. (2015) 5, 17777.
25. F. Meinardi, S. Ehrenberg, L. Dhamo, F. Carulli, M. Mauri, F. Bruni, R. Simonutti, U. Kortshagen, S. Brovelli, Nat. Photon. (2017) 11, 177.
26. R. Hardman, Environ. Health Persp. (2006) 114, 165.
27. J. Wang, P. Zhang, C. Huang, G. Liu, K. C. F. Leung, Y. X. J. Wang, Langmuir (2015) 31, 8063.
28. a) S. N. Baker, G. A. Baker, Angew. Chem. (2010) 122, 6876; b) Angew. Chem. Int. Ed. (2010) 49, 6726.
29. Y. P. Sun, B. Zhou, Y. Lin, W. Wang, K. A. Shirai Fernando, P. Pathak, M. J. Meziani, B. A. Harruff, X. Wang, H. Wang, P. G. Luo, H. Yang, M. E. Kose, B. Chen, L. M. Veca, S. Y. Xie, J. Am. Chem. Soc. (2006) 128, 7756.
30. X. Xu, R. Ray, Y. Gu, H. J. Ploehn, L. Gearheart, K. Raker, W. A. Scrivens, J. Am. Chem. Soc. (2004) 126, 12736.
31. A. B. Bourlinos, A. Stassinopoulos, D. Anglos, R. Zboril, V. Georgakilas, E. P. Giannelis, Chem. Mater. (2008) 20, 4539.
32. A. B. Bourlinos, A. Stassinopoulos, D. Anglos, R. Zboril, V. Georgakilas, M. Karakassides, E. P. Giannelis, Small (2008) 4, 455.
33. L. Cao, X. Wang, M. J. Meziani, F. Lu, H. Wang, P. G. Luo, Y. Lin, B. A. Harruff, L. M. Veca, D. Murry, S. Y. Xie, Y. P. Sun, J. Am. Chem. Soc. (2007) 129, 11318.
34. S. C. Ray, A. Saha, N. R. Jana, R. Sarkar, J. Phys. Chem. C (2009) 113, 18546.
35. Y. Li, Y. Hu, Y. Zhao, G. Shi, L. Deng, Y. Hou, L. Qu, Adv. Mater. (2011) 23, 776.
36. S. Zhu, J. Zhang, C. Qiao, S. Tang, Y. Li, W. Yuan, B. Li, L. Tian, F. Liu, R. Hu, H. Gao, H. Wei, H. Zhang, H. Sun, B. Yang. Chem. Commun. (2011) 47, 6858.
37. Y. Q. Zhang, D. K. Ma, Y. Zhuang, X. Zhang, W. Chen, L. L. Hong, Q. X. Yan, K. Yu, S. M. Huang, J. Mater. Chem. (2012) 22, 16714.
38. S. Qu, D. Zhou, D. Li, W. Ji, P. Jing, D. Han, L. Liu, H. Zeng, D. Shen, Adv. Mater. (2016) 28, 3516.
39. W. Kwon, G. Lee, S. Do, T. Joo, S. W. Rhee, Small (2014) 10, 506.
40. F. Wang, S. Pang, L. Wang, Q. Li, M. Kreiter, C. Y. Liu, Chem. Mater. (2010) 22, 4528.
41. V. Georgakilas, J. A. Perman, J. Tucek, R. Zboril, Chem. Rev. (2015) 115, 4744.
42. V. I. Klimov, T. A. Baker, J. Lim, K. A. Velizhanin, H. McDaniel, ACS Photonics (2016) 3, 1138.
43. Y. Li, P. Miao, W. Zhou, X. Gong, X. Zhao, J. Mater. Chem. A (2017) 5, 21452.
44. a) S. Zhu, Q. Meng, L. Wang, J. Zhang, Y. Song, H. Jin, K. Zhang, H. Sun, H. Wang, B. Yang, Angew. Chem. (2013) 125, 4045; b) Angew. Chem. Int. Ed. (2013) 52, 3953.
45. H. Li, K. Wu, J. Lim, H. J. Song, V. I. Klimov, Nat. Energy (2016) 1, 16157.
46. W. W. Yu, L. Qu, W. Guo, X. Peng, Chem. Mater. (2003) 15, 2854.

1. A luminescent solar concentrator (LSC) comprising a metal-free emitter.

2. A luminescent solar concentrator (LSC) comprising a carbon-based emitter.

3. A luminescent solar concentrator (LSC) having an emitter that comprises carbon material.

4. A luminescent solar concentrator (LSC) having an emitter that comprises colloidal carbon quantum dots (C-dots).

5. A luminescent solar concentrator (LSC) having an emitter that comprises surface-modified colloidal carbon quantum dots (C-dots).

6. A luminescent solar concentrator (LSC), which is metal-free.

7. A luminescent solar concentrator (LSC) comprising carbon material and a polymer material.

8. A luminescent solar concentrator (LSC) comprising colloidal carbon quantum dots (C-dots).

9. A luminescent solar concentrator (LSC) comprising colloidal carbon quantum dots (C-dots) and a polymer material.

10. A luminescent solar concentrator (LSC) comprising surface-modified colloidal carbon quantum dots (C-dots).

11. A luminescent solar concentrator (LSC) comprising surface-modified colloidal carbon quantum dots (C-dots) and a polymer material.

12. A luminescent solar concentrator (LSC) comprising a substrate having a surface coated with a material comprising carbon and a polymer.

13. A luminescent solar concentrator (LSC) comprising a substrate having a surface coated with a material comprising colloidal carbon quantum dots (C-dots) and a polymer.

14. A luminescent solar concentrator (LSC) comprising a substrate having a surface coated with a material comprising surface-modified colloidal carbon quantum dots (C-dots) and a polymer.

15. A matrix for use in the manufacture of a luminescent solar concentrator (LSC), the matrix comprising a carbon material and a polymer material.

16. A matrix for use in the manufacture of a luminescent solar concentrator (LSC), the matrix comprising colloidal carbon quantum dots (C-dots) and a polymer material.

17. A matrix for use in the manufacture of a luminescent solar concentrator (LSC), the matrix comprising surface-modified colloidal carbon quantum dots (C-dots) and a polymer material.

18. A substrate for use in the manufacture of a luminescent solar concentrator (LSC), the substrate being coated with a mixture comprising a carbon material and a polymer material.

19. A substrate for use in the manufacture of a luminescent solar concentrator (LSC), the substrate being coated with a mixture comprising colloidal carbon quantum dots (C-dots) and a polymer material.

20. A substrate for use in the manufacture of a luminescent solar concentrator (LSC), the substrate being coated with a mixture comprising surface-modified colloidal carbon quantum dots (C-dots) and a polymer material.

21. A composition for use in the manufacture of a luminescent solar concentrator (LSC), the composition comprising a carbon material and a polymer material and/or a monomers material and/or a pre-polymer material and/or a precursor polymer material.

22. A composition for use in the manufacture of a luminescent solar concentrator (LSC), the composition comprising colloidal carbon quantum dots (C-dots) and a polymer material and/or a monomers material and/or a pre-polymer material and/or a precursor polymer material.

23. A composition for use in the manufacture of a luminescent solar concentrator (LSC), the composition comprising surface-modified colloidal carbon quantum dots (C-dots) and a polymer material and/or a monomers material and/or a pre-polymer material and/or a precursor polymer material.

24. A method of manufacturing a luminescent solar concentrator (LSC), comprising: preparing a carbon material; providing a polymer material; mixing the carbon material and the polymer material to obtain the LSC.

25. A method of manufacturing a luminescent solar concentrator (LSC), comprising: preparing colloidal carbon quantum dots (C-dots); providing a polymer material; mixing the C-dots and the polymer material to obtain the LSC.

26. A method of manufacturing a luminescent solar concentrator (LSC), comprising: preparing colloidal carbon quantum dots (C-dots); providing a polymer material; mixing the surface-modified C-dots and the polymer material to obtain the LSC.

27. A method of manufacturing a luminescent solar concentrator (LSC), comprising: preparing a carbon material; providing monomers material; mixing the carbon material and the monomers material; and conducting polymerization using an initiator to obtain the LSC.

28. A method of manufacturing a luminescent solar concentrator (LSC), comprising: preparing colloidal carbon quantum dots (C-dots); providing monomers material; mixing the C-dots and the monomers material; and conducting polymerization using an initiator to obtain the LSC.

29. A method of manufacturing a luminescent solar concentrator (LSC), comprising: preparing surface-modified colloidal carbon quantum dots (C-dots); providing monomers material; mixing the surface modified C-dots and the monomers material; and conducting polymerization using an initiator to obtain the LSC.

30. A method of manufacturing a luminescent solar concentrator (LSC), comprising: preparing a carbon material; providing a substrate and a polymer material; mixing the carbon material, the polymer material and the solvent; and forming a layer of the mixture on a surface of the substrate.

31. A method of manufacturing a luminescent solar concentrator (LSC), comprising: preparing colloidal carbon quantum dots (C-dots); providing a substrate and a polymer material; mixing the C-dots, the polymer material and the solvent; and forming a layer of the mixture on a surface of the substrate.

32. A method of manufacturing a luminescent solar concentrator (LSC), comprising: preparing surface-modified colloidal carbon quantum dots (C-dots); providing a substrate and a polymer material; mixing the surface modified C-dots, the polymer material and the solvent; and forming a layer of the mixture on a surface of the substrate.

33. A method of manufacturing a luminescent solar concentrator (LSC), comprising: preparing a carbon material; providing a polymer material; mixing the carbon material, the polymer material and the solvent; providing a mold constituted by first and second substrates separated by a spacer; and injecting the mixture into the mold.

34. A method of manufacturing a luminescent solar concentrator (LSC), comprising: preparing colloidal carbon quantum dots (C-dots); providing a polymer material; mixing the C-dots, the polymer material and the solvent; providing a mold constituted by first and second substrates separated by a spacer; and injecting the mixture into the mold.

35. A method of manufacturing a luminescent solar concentrator (LSC), comprising: preparing surface-modified colloidal carbon quantum dots (C-dots); providing and a polymer material; mixing the surface modified C-dots, the polymer material and the solvent; providing a mold constituted by first and second substrates separated by a spacer; and injecting the mixture into the mold.

36. A method for preparing a matrix for use in the manufacture of a luminescent solar concentrator (LSC), the method comprising: preparing a carbon material; providing a polymer material; and mixing the carbon material and the polymer material to obtain the matrix.

37. A method for preparing a matrix for use in the manufacture of a luminescent solar concentrator (LSC), the method comprising: preparing colloidal carbon quantum dots (C-dots); providing a polymer material; and mixing the C-dots and the polymer material to obtain the matrix.

38. A method for preparing a matrix for use in the manufacture of a luminescent solar concentrator (LSC), the method comprising: preparing surface-modified colloidal carbon quantum dots (C-dots); providing a polymer material; and mixing the surface-modified C-dots and the polymer material to obtain the matrix.

39. A method for preparing a matrix for use in the manufacture of a luminescent solar concentrator (LSC), the method comprising: preparing a carbon material; providing monomers material; mixing the carbon material and the monomers material; and conducting polymerization using an initiator to obtain the matrix.

40. A method for preparing a matrix for use in the manufacture of a luminescent solar concentrator (LSC), the method comprising: preparing colloidal carbon quantum dots (C-dots); providing monomers material; mixing the C-dots and the monomers material; and conducting polymerization using an initiator to obtain the matrix.

41. A method for preparing a matrix for use in the manufacture of a luminescent solar concentrator (LSC), the method comprising: preparing surface-modified colloidal carbon quantum dots (C-dots); providing monomers material; mixing the surface modified C-dots and the monomers material; and conducting polymerization using an initiator to obtain the matrix.

42. A device for converting sunlight into electricity, comprising a luminescent solar concentrator (LSC) as defined in any one of claims 1-14 and one or more photovoltaic cells provided at edges of the LSC.

43. A device for converting sunlight into electricity, comprising at least one matrix as defined in any one of claims 15-17 and one or more photovoltaic cells provided at edges of the matrix.

44. A device for converting sunlight into electricity, comprising at least one substrate as defined in any one of claims 18-20 and one or more photovoltaic cells provided at edges of the substrate.

45. A method of manufacturing a device for converting sunlight into electricity, comprising using a composition as defined in any one of claims 21-23.

46. A luminescent solar concentrator or matrix or substrate or composition or method or device according to any one of claims 1-45, wherein the surface-modified colloidal carbon quantum dots are modified with a base which is organic or inorganic; preferably, the base is an amine, NaOH or KOH.

47. A luminescent solar concentrator or matrix or substrate or composition or method or device according to any one of claims 1-45, wherein the surface-modified colloidal carbon quantum dots are modified with an amine; preferably the amine is a long carbon-chain amine; more preferably an amine having a carbon chain of more than about 6 carbons.

48. A luminescent solar concentrator or matrix or substrate or composition or method or device according to any one of claims 1-45, wherein the surface-modified colloidal carbon quantum dots are modified with oleyamine.

49. A luminescent solar concentrator or matrix or substrate or composition or method or device according to any one of claims 1-48, having an input area (or surface sheet oriented toward the energy source) in a range between at least about 25 to about 2500 cm².

50. A luminescent solar concentrator or matrix or substrate or composition or method or device according to any one of claims 1-49, having a thickness between about 20 μm to 2 mm; preferably between about 20 μm to about 150 μm; preferably between about 50 μm to 100 μm; preferably between about 1.5 mm to about 2.5 mm; preferably around 2 mm.

51. A luminescent solar concentrator or matrix or substrate or composition or method or device according to any one of claims 1-50, wherein the polymer material comprises poly(lauryl methacrylate) (PLMA), polyvinylpyrrolidone (PVP), poly(vinyl alcohol), polyethylene glycols with average mol. wt. 1,000-1,000,000, or a combination thereof.

52. A luminescent solar concentrator or matrix or substrate or composition or method or device according to any one of claims 1-51, wherein the monomers material comprises an alkyl acrylate, preferably an alkyl acrylate having about 4-12 carbon atoms in the alkyl group or an alkyl acrylate having an average of about 4-12 carbon atoms in its alkyl groups (CH₂═C(CH₃)COOCH₂(CH₂)ₙCH₃ wherein n=4-12, CH₂═C(H)COOCH₂(CH₂)ₙCH₃ wherein n=4-12) or an alkyl methacrylate such as ethylene glycol dimethacrylate (EGDM) or lauryl methacrylate; or a combination thereof.

53. A luminescent solar concentrator or matrix or substrate or composition or method or device according to any one of claims 1-52, wherein the matrix is poly(lauryl methacrylate) (PLMA) polymer matrix.

54. A luminescent solar concentrator or matrix or substrate or composition or method or device according to any one of claims 1-53, wherein the C-dots are embedded in poly(lauryl methacrylate) (PLMA) polymer matrix.

55. A luminescent solar concentrator or matrix or substrate or composition or method or device according to any one of claims 1-52, wherein the C-dots are mixed with polyvinylpyrrolidone (PVP).

56. A composition according to any one of claims 21-23, further comprising a solvent, and a concentration of the C-dots in the mixture is between about 5-100 mg/mL or is about 15 mg/mL.

57. A method according to any one of claims 30-32, wherein the layer is formed on the surface of the substrate by spray deposition, spin coating or a combination thereof; preferably the substrate is a glass substrate.

58. A method according to any one of claims 33-35, wherein the substrate is flexible or rigid and/or wherein the spacer is made of a flexible material, preferably the spacer is a flexible silicon rubber; preferably a thickness of the spacer is between about 1.5 mm to about 2.5 mm, preferably about 2 mm.
